(19) United States
(12) Patent Application Publication
(10) Pub. No.: US 2025/0035965 A1
(43) Pub. Date: Jan. 30, 2025

(54) CONTINUOUS COMPOSITIONAL GRADING FOR REALIZATION OF LOW CHARGE CARRIER BARRIERS IN ELECTRO-OPTICAL HETEROSTRUCTURE SEMICONDUCTOR DEVICES

(71) Applicant: MELLANOX TECHNOLOGIES, LTD., Yokneam (IL)

(72) Inventors: Oren STEINBERG, Tal Shahar (IL); Anders Gösta LARSSON, Hovås, (SE); Attila FÜLÖP, Göteborg (SE); Elad MENTOVICH, Tel Aviv (IL); Isabelle CESTIER, Haifa (IL); Moshe B. ORON, Rehovot (IL)

(73) Assignee: MELLANOX TECHNOLOGIES, LTD., Yokneam (IL)

(21) Appl. No.: 18/911,975

(22) Filed: Oct. 10, 2024

Related U.S. Application Data
(63) Continuation-in-part of application No. 17/881,927, filed on Aug. 5, 2022, now Pat. No. 12,132,137.

(51) Int. Cl. G02F 1/017; G02F 1/015; H01L 31/0232; H01L 31/0304; H01L 31/109

(52) U.S. Cl. CPC G02F 1/01708; G02F 1/0157; H01L 31/02327; H01L 31/03046; H01L 31/109; G02F 2202/101; G02F 2202/102; G02F 2202/108

(57) ABSTRACT

Processes and devices for continuous compositional grading in photodetectors and electro-absorption modulators (EAM) are provided. An example photodetector includes a multi-layered structure comprising a collector region, an absorber region, a grading layer, and a peripheral layer, all aligned along a detection axis. The grading layer, positioned adjacent to the absorber region, includes multiple sub-layers that define a continuous compositional grading to facilitate smooth carrier transport and reduce recombination. Similarly, an example electro-absorption modulator (EAM) device includes a waveguide mesa formed on a semiconductor substrate, comprising a multi-quantum well (MQW) core layer, upper and lower near-core cladding layers, and upper and lower central cladding layers. The EAM device features both upper and lower grading layers, each positioned between the near-core cladding layers and the adjacent central cladding layers. These grading layers include multiple sub-layers that define a continuous compositional grading, facilitating smooth transitions between the MQW core and surrounding cladding layers.

### CROSS REFERENCE TO RELATED APPLICATIONS

This application is a Continuation-in-Part (CIP) of U.S. patent application Ser. No. 17/881,927, filed on Aug. 5, 2022, entitled “CONTINUOUS COMPOSITIONAL GRADING FOR REALIZATION OF LOW CHARGE CARRIER BARRIERS IN ELECTRO-OPTICAL HETEROSTRUCTURE SEMICONDUCTOR,” which is hereby incorporated by reference in its entirety. This application includes subject matter not disclosed in the parent application, and it claims priority to the parent application to the extent allowed by law.

### TECHNOLOGICAL FIELD

Embodiments of the present disclosure relate generally to systems and methods for continuous compositional grading for realization of low charge carrier barriers in electro-optical heterostructure semiconductor devices, wherein a first semiconductor layer associated with a first bandgap value is formed onto one or more semiconductor layers, a grading layer is formed onto the first semiconductor layer, and a second semiconductor layer associated with a second bandgap value is formed onto the grading layer.

### BACKGROUND

Semiconductor chips are typically used in devices for conducting and directing electricity among components of the device. These chips are often formed of a plurality of layers, each of which are associated with various characteristic or parameters (e.g., bandgaps or the like). These semiconductor chips often attempt to provide continuous electron mobility, such that electrons are not trapped between different bandgaps which may in turn lead to lower speed in electron movement within the semiconductor and a reduced amount of electron collection. Through applied effort, ingenuity and innovation, various identified deficiencies and problems associated with semiconductor chips have been solved by developing solutions that are configured in accordance with the embodiments of the present disclosure, many examples of which are described in detail herein.

### GENERAL DESCRIPTION

Example embodiments of the present disclosure relate generally to improved systems and methods for continuous compositional grading for realization of low charge carrier barriers in electro-optical heterostructure semiconductor devices, such as photodetectors and electro-absorption modulators. The details of some embodiments of the subject matter described in this specification are set forth in the accompanying drawings and the description below. Other features, aspects, and advantages of the subject matter will become apparent from the description, the drawings, and the claims.

In one aspect, a photodetector is presented. The photodetector comprises: a collector region disposed on one or more semiconductor layers, wherein the collector region comprises collector material that is substantially transparent to an operational wavelength range of the photodetector; an absorber region disposed above the collector region along a detection axis of the photodetector; a grading layer disposed adjacent the absorber region along the detection axis, wherein the grading layer comprises a plurality of layers defining a continuous compositional grading; and a peripheral layer disposed above the grading layer along the detection axis, wherein the operational wavelength range is approximately 940 nm to 1700 nm.

In some embodiments, the collector region has a first thickness in a direction that is substantially parallel to the detection axis, and wherein the absorber region has a second thickness in the direction that is substantially parallel to the detection axis.

In some embodiments, the photodetector further comprises: an optical window disposed above the absorber region such that light passes through the optical window before reaching the absorber region, wherein the optical window is configured for use with a multi-mode optical fiber.

In some embodiments, the absorber region comprises absorber material, wherein the absorber material comprises at least one of indium gallium arsenide (InGaAs), indium gallium arsenide phosphide (InGaAsP), or indium gallium aluminum arsenide (InGaAlAs).

In some embodiments, the absorber material is lattice-matched to indium phosphide (InP).

In some embodiments, the collector region comprises collector material, wherein the collector material comprises at least one of indium phosphide (InP), indium gallium arsenide phosphide (InGaAsP), or indium gallium aluminum arsenide (InGaAlAs).

In some embodiments, the collector material is lattice-matched to indium phosphide (InP).

In some embodiments, the peripheral layer is lattice-matched to the collector material.

In some embodiments, the peripheral layer comprises p-type doped material, wherein the p-type doped material comprises at least one of indium phosphide (InP), indium aluminum arsenide (InAlAs), indium gallium arsenide phosphide (InGaAsP), or indium gallium aluminum arsenide (InGaAlAs).

In some embodiments, the grading layer is disposed between the absorber region and the peripheral layer.

In some embodiments, the grading layer is disposed between the absorber region and the collector region.

In another aspect, an electro-absorption modulator (EAM) device is presented. The EAM device comprises: a semiconductor substrate; and a waveguide mesa formed on the semiconductor substrate, wherein the waveguide mesa further comprises: a multi-quantum well (MQW) core layer; an upper near-core cladding layer disposed above the MQW layer; an upper grading layer disposed adjacent the upper near-core cladding layer, wherein the upper grading layer comprises a plurality of layers defining a continuous compositional grading; and an upper central cladding layer disposed above the upper grading layer.

In some embodiments, the MQW layer comprises gallium arsenide (GaAs), indium phosphide (InP) based semiconductor materials, or silicon based semiconductor.

In some embodiments, the MQW layer comprises III-V semiconductor materials, wherein the III-V semiconductor materials comprises at least one of indium aluminum gallium arsenide (InAlGaAs), indium gallium arsenide phosphide (InGaAsP), silicon germanium (SiGe), or Si—SiGe composition.

In some embodiments, MQW is formed using a single epitaxial growth process.

In some embodiments, the waveguide mesa further comprises: a lower near-core cladding layer disposed below the MQW layer; a lower grading layer disposed adjacent the lower near-core cladding layer, wherein the lower grading layer comprises a plurality of layers defining a continuous compositional grading; and a lower central cladding layer disposed below the lower grading layer.

In some embodiments, the upper near-core cladding layer and the lower near-core cladding layer comprise at least one of n-type doped aluminum gallium arsenide (AlGaAs) or indium gallium arsenide phosphide (InGaAsP) semiconductor material or p-type doped aluminum AlGaAs or InGaAsP semiconductor material.

In some embodiments, the upper central cladding layer and the lower central cladding layer comprise at least one of n-type doped indium phosphide (InP) semiconductor material or p-type doped InP semiconductor material.

In some embodiments, the upper grading layer is disposed between the MQW layer and the upper near-core cladding layer, and the lower grading layer is disposed between the MQW layer and the lower near-core cladding layer.

### BRIEF DESCRIPTION OF THE DRAWINGS

Having thus described the disclosure in general terms, reference will now be made to the accompanying drawings, which are not necessarily drawn to scale, and wherein:

FIG. 1A illustrates an example cross-section view of a layered structure used to generate a semiconductor device, in accordance with one or more embodiments of the present disclosure;

FIG. 1B illustrates an example cross-section view of a layered structure including a plurality of grading layers used to generate a semiconductor device, in accordance with one or more embodiments of the present disclosure;

FIG. 1C illustrates an example cross-section view of a photodetector having layered structure including a plurality of grading layers, in accordance with one or more embodiments of the present disclosure;

FIG. 1D illustrates an example cross-section view of an electro-absorption modulator (EAM) device having a layered structure including a plurality of grading layers, in accordance with one or more embodiments of the present disclosure;

FIG. 2 illustrates an example bandgap diagram for the example layered structure of FIG. 1A, in accordance with one or more embodiments of the present disclosure;

FIG. 3 illustrates an example flowchart of the process to generate the layered structure, in accordance with one or more embodiments of the present disclosure;

FIG. 4A illustrates a conduction band diagram of the layered structure's performance of the conduction band, in accordance with one or more embodiments of the present disclosure; and

FIG. 4B illustrates a frequency response comparison of the layered structure's performance, in accordance with one or more embodiments of the present disclosure.

### DETAILED DESCRIPTION

Example embodiments will now be described more fully hereinafter with reference to the accompanying drawings, in which some, but not all, embodiments are shown. Indeed, the embodiments may take many different forms and should not be construed as limited to the embodiments set forth herein; rather, these embodiments are provided so that this disclosure will satisfy applicable legal requirements. Like reference numerals refer to like elements throughout. The terms “exemplary” and “example” as may be used herein are not provided to convey any qualitative assessment, but instead merely to convey an illustration of an example. As used herein, terms such as “front,” “rear,” “top,” “inside,” “outside,” “inner,” “outer,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

Furthermore, for purposes of this disclosure, terms such as “above,” “below,” “adjacent,” “disposed on,” and similar positional terms may be used to describe the relative positioning of various layers and components within the described devices, such as photodetectors and electro-absorption modulators (EAM). These terms are intended to convey general spatial relationships and are not limited to direct or immediate contact unless explicitly stated otherwise. For example, “above” and “below” refer to positions relative to a defined axis, such as the detection axis in the photodetector or the layering sequence in the EAM device, and do not necessarily require physical contact between layers.

The term “adjacent” may refer to both direct contact and indirect contact where one or more intervening layers or materials may be present. Thus, a layer described as “adjacent” to another layer can be immediately above, immediately below, or near the referenced layer with intervening structures. Similarly, terms like “disposed on” and “disposed below” indicate relative positioning rather than mandatory direct contact, allowing for variations in the structural design where layers may be separated by other functional elements.

The aforementioned positional descriptors are intended to provide flexibility in the interpretation of the disclosed embodiments and should not be construed as limiting the scope of the invention to specific configurations unless expressly specified in the claims. Variations and modifications in positioning and layering that maintain the functional relationships described herein are considered within the scope of the disclosure.

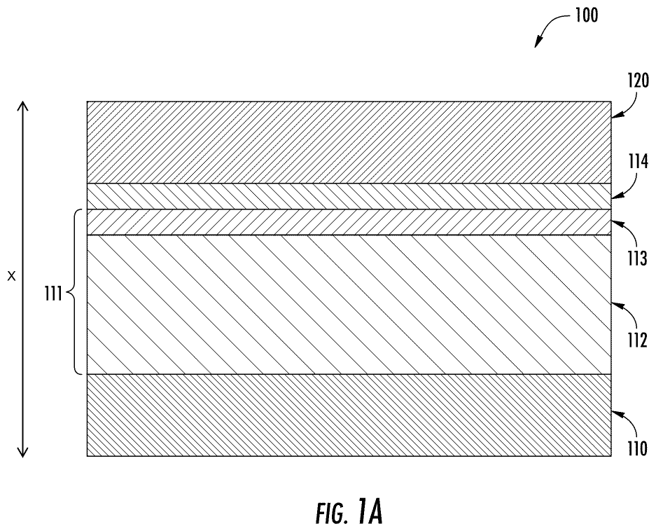

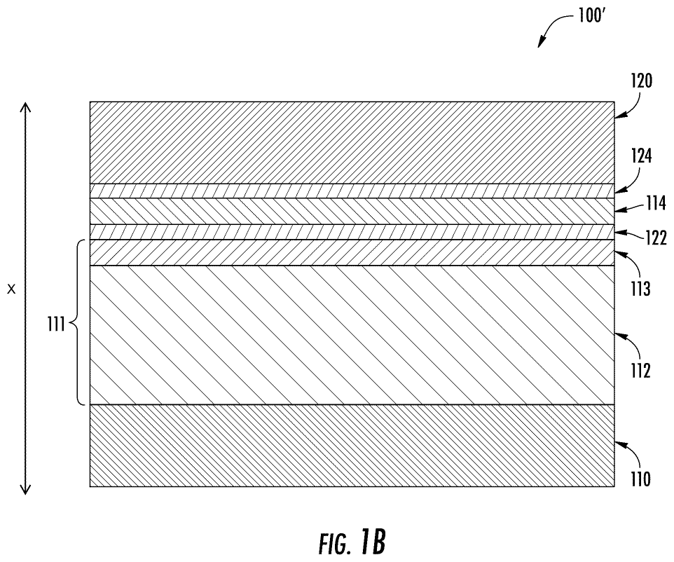

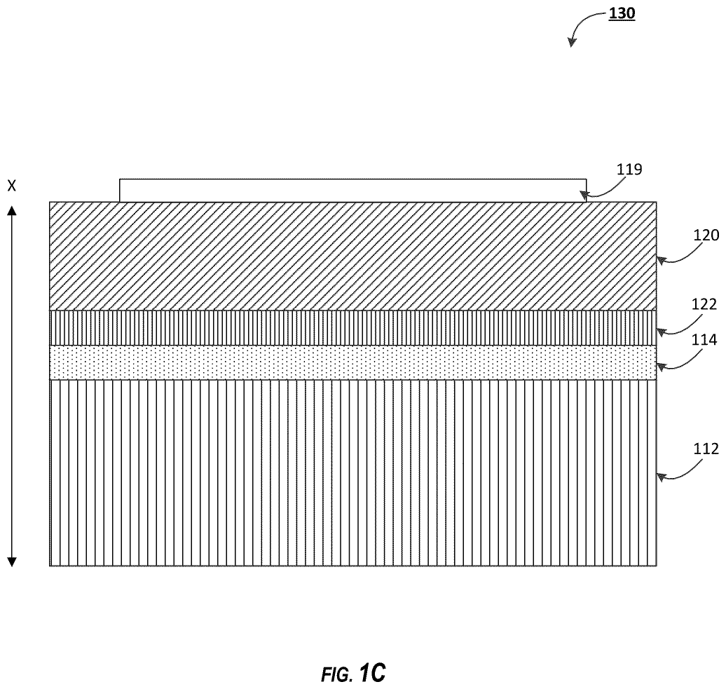

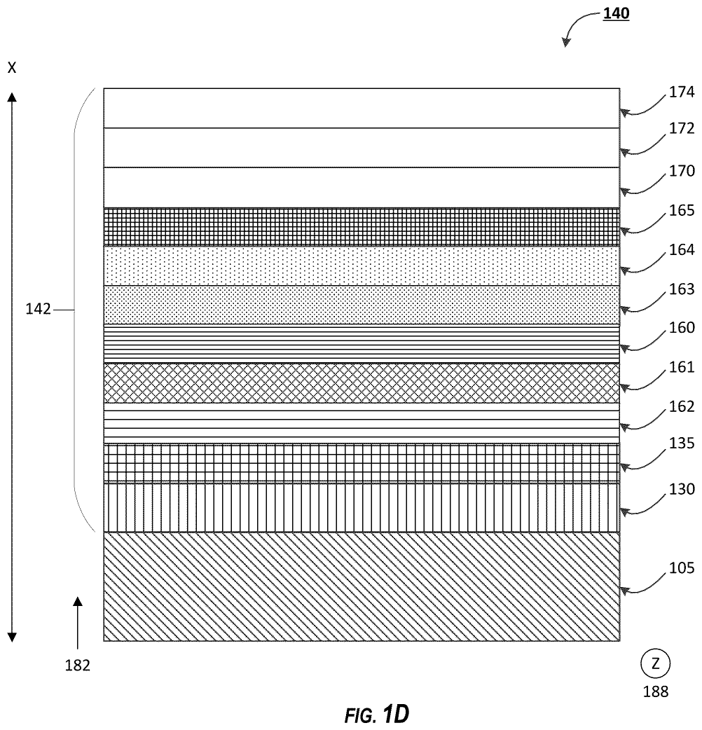

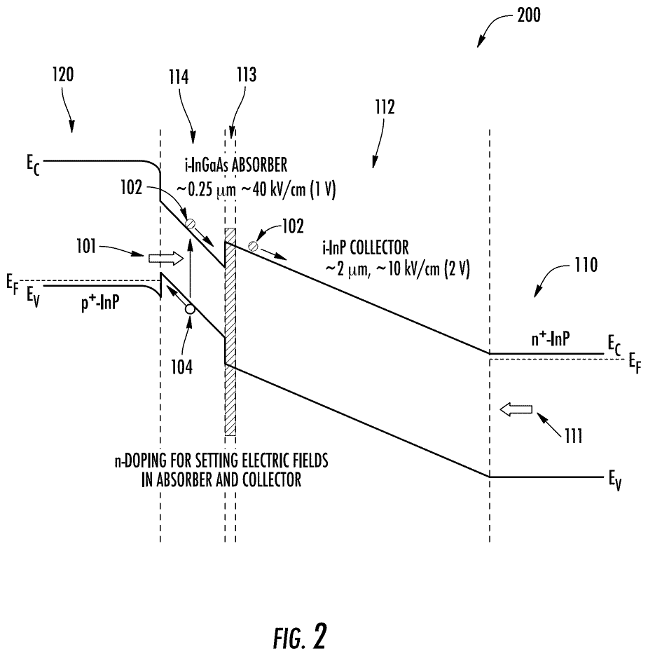

A layered structure described herein may generally be understood to be a stack of materials that is used to create a semiconductor device. For example, such materials may include a plurality of peripheral layers, an absorption layer, and a collector region including drift and collector layers. Within this layered structure free electrons and free holes may be trapped within the materials. Such a layered structure and its individual materials are described more fully below with respect to FIGS. 1A, 1B, 1C, 1D, and 2.

Various embodiments of the present disclosure are provided to overcome and/or mitigate the issues with semiconductors that include different layers and materials of different bandgaps where free electrons and free holes may be trapped as they move from one material to another in generating conductivity. For instance, in a system of an InP-based Photo Diode (PD), with a InGaAs alloy—which is lattice-matched to the InP—with the InGaAs alloy acting as the absorbing layer and the InP layer acting as the collector layer, there may be a bandgap difference of at least 0.6 eV (e.g., the bandgap of the InGaAs lattice matched to the InP is 0.75 eV and the bandgap of InP is 1.35 eV, at room temperature) that may trap a free electron or free hole as it moves through the layered structure of the semiconductor.

In some embodiments, and for high-speed PD devices, a potential speed limiting effect may be the trapping of photogenerated electrons and holes at the InGaAs/InP interfaces where the potential barriers are large in both the conduction band (e.g., 240 meV) and the valence band (360 meV). In this manner, the photogenerated electrons and holes (i.e., free electrons and free holes) may be trapped and/or slowed down by the potential barriers in both the conduction band and the valence band.

In various embodiments, the layered structure including continuous grading layers are formed within a layered structure that is used to generate a semiconductor, such as that shown explicitly in FIG. 1B and implicitly in FIG. 1A. In some embodiments, the layered structure may be provided by with photodetector device such that light may be captured by the photodetector and fed into the layered structure. In various embodiments, the layered structure includes at least one separate light absorption region (e.g., absorption layer) and at least one collector region comprising drift/collector layers. For example, in various embodiments, the layered structure includes the absorber region (i.e., comprising the absorption layer) and the collector region. Although these regions do not overlap, but they touch such that electrons may move between the absorber region and the collector region.

In some embodiments, a drift layer 113 may be doped so as to control the electric fields in the absorption region 114 and the collector region 111 (e.g., which comprises drift layer 113 and collection layer 112). For example, the drift layer 113 may be doped so that when an appropriate bias voltage is applied to the photodetector comprising the layered structure, an electric field is generated within the collector layer 112 and the absorption region 114. The electric filed causes the collector layer 112, drift layer 113, collection region 111, absorption layer 114, and/or absorption region 114 to be substantially depleted of free charge carriers (i.e., the charge carriers which carry the free electrons and free holes within the layered structure).

FIG. 1A illustrates an example cross-section view of a layered structure that does not explicitly show a plurality of continuous grading layers (e.g., 124 and 122 as shown in FIG. 1B). FIG. 1B illustrates an example cross-section view of a layered structure 100′ comprising a plurality of grading layers 122 and 124, where the plurality of grading layers 122 and 124 are provided within the layered structure to provide a graded structure for the electron and hole movement, in accordance with one or more embodiments of the present disclosure. FIG. 2 illustrates an example bandgap diagram for the example layered structure of FIG. 1A, that indicates the various areas of bandgaps associated with the layers of the layered structure of FIG. 1A.

In some embodiments, the layered structure comprising the grading layers 100′ and the layered structure that include the grading layers 124 and 122, may be configured to detect light in a particular wavelength range, such as the wavelength range of 940-1150 nm. In some embodiments, the contact layers of the light (e.g., the peripheral layers 110 and/or 120 of FIGS. 1A and 1B) may be transparent so as to allow light to pass through such that the light is transferred to the absorption region 114. In some embodiments, and similar to the peripheral layers, the collector region 111 (e.g., the collector layer 112 and drift layer 113 also referred to as the intermediate layer) may be transparent so the light is not absorbed in the collection region if it is first contacted at peripheral layer 110. For instance, light may be contacted through a top peripheral layer (e.g., peripheral layer 120) that is directly adjacent to the absorption layer 114 and transmitted to the absorption layer 114, or light may be contacted through the bottom peripheral layer 110 and carried through the collector region (112 and 113) to the absorption region 114. In some embodiments, and once the light has been absorbed in the absorption layer 114, electrons and holes may be generated within the absorption layer 114.

In an example embodiment, the layered structure may be configured to create a photodetector. FIG. 1C illustrates an example cross-section view of a photodetector 130 having layered structure including a plurality of grading layers, in accordance with one or more embodiments of the present disclosure. As shown in FIG. 1C, the photodetector 130 may include a collector region 112, an absorber region 114, a grading layer 122, and a peripheral layer 120, all aligned along a defined detection axis, X.

The collector region 112 may be disposed on one or more underlying semiconductor layers. The collector region 112 may be configured to be substantially transparent to the operational wavelength range of the photodetector 130, approximately 940 nm to 1700 nm, allowing incident light to pass through with minimal absorption. This transparency allows incident light to pass through the collector region 112 with minimal loss, enabling efficient light absorption in the subsequent layers. The collector region 112 may be composed of materials such as indium phosphide (InP), indium gallium arsenide phosphide (InGaAsP), or indium gallium aluminum arsenide (InGaAlAs), chosen for their compatibility with the device structure and their transparency within the specified wavelength range. In some embodiments, the collector material 112 of the photodetector 130 may be lattice-matched to indium phosphide (InP). Lattice matching to InP reduces strain and dislocations, which can otherwise degrade the performance of the photodetector 130 by increasing recombination rates and reducing carrier mobility.

The absorber region 114 may be positioned above the collector region 112 to capture the transmitted light and generate photogenerated carriers. The absorber region 114 may be formed from materials such as indium gallium arsenide (InGaAs), indium gallium arsenide phosphide (InGaAsP), or indium gallium aluminum arsenide (InGaAlAs), which may be selected for their effective absorption properties within the designated wavelength range. These absorber materials may be lattice-matched to indium phosphide (InP) for structural compatibility and minimizing defects at the interfaces. The absorber region 114 may have a specific thickness that is optimized to balance absorption efficiency and carrier transport speed, reducing recombination losses while maintaining high responsivity.

The grading layer 122 may be disposed adjacent to the absorber region 114 along the detection axis. In one embodiment, the grading layer 122 may be disposed between the absorber region 114 and the peripheral layer 120 along the detection axis, X. Additionally or alternatively, the grading layer 122 may be disposed between the absorber region 114 and the collector region 112 along the detection axis, X (not shown). The grading layer 122 may include a plurality of sub-layers, each contributing to a continuous compositional grading. As described herein, the continuous grading may mitigate potential barriers that typically arise from abrupt material transitions, thereby improving the movement of photogenerated carriers (electrons and holes) through the structure. By eliminating distinct steps between the layers, the grading layer 122 reduces carrier trapping and recombination.

A peripheral layer 120 may be disposed above the grading layer 122 to serves as an outermost layer of the photodetector. The peripheral layer 120, which may consist of materials such as indium phosphide (InP) or related compounds, can be doped to either p-type or n-type, depending on the intended application and performance requirements. The peripheral layer 120 may provide a robust interface for light entry and is engineered to support effective carrier extraction from the absorber region 114. In some embodiments, the peripheral layer 120 may be lattice-matched to the collector material, maintaining continuity in the crystal structure across the photodetector.

The photodetector 130 may also include an optical window 119 positioned above the peripheral layer 120, configured to allow light to pass through before reaching the absorber region 114. The optical window 119 may be composed of a dielectric material such as silicon dioxide, silicon nitride, or similar, with its thickness optimized for the target wavelength to minimize reflection and improve light transmission into the absorber region 114. The optical window 119 may be configured to be compatible with multi-mode optical fibers, enhancing the photodetector's ability to couple light efficiently from external sources. The inclusion of the optical window 119 supports optimal light delivery to the absorber region, further improving the device's sensitivity and performance in various optical communication applications.

In another example embodiment, the layered structure may be configured to create an electro-absorption modulator (EAM) device. The EAM device may include a semiconductor substrate, a waveguide mesa formed on the substrate, and an electrode structure configured to apply an electric field across the waveguide mesa. The waveguide mesa may include a multi-quantum well (MQW) core layer, which serves as the active region for modulating optical signals. The MQW core layer may be composed of semiconductor materials such as gallium arsenide (GaAs), indium phosphide (InP), or other III-V semiconductor compounds, including indium aluminum gallium arsenide (InAlGaAs), indium gallium arsenide phosphide (InGaAsP), and silicon germanium (SiGe). These materials are selected for their ability to support efficient electro-optical modulation at the desired operational wavelengths.

The MQW layer may be sandwiched between upper and lower near-core cladding layers that provide optical confinement and improve the modulation efficiency of the MQW region. As such, the upper and lower near-core cladding layers may be peripheral layers above and below the MQW layer, respectively. The upper and lower near-core cladding layers may have a refractive index lower than the MQW layer, forming a waveguide structure that confines light within the core. Such confinement may increase the interaction between the optical signal and the electric field across the MQW, thereby modulating the light's intensity. The near-core cladding layers may be composed of materials such as aluminum gallium arsenide (AlGaAs) or indium gallium arsenide phosphide (InGaAsP), chosen to match the lattice structure of the MQW layer. Doping levels and material compositions may be adjusted to achieve the required refractive index and confinement properties. The MQW layer, along with the near-core cladding layers, can be grown in a single epitaxial growth process, ensuring uniformity and precise control over the material composition and interface quality. Such a single growth process may reduce defects and lattice mismatches at the interfaces. The thickness and index profile of the upper and lower near-core cladding layers may be configured to minimize optical losses while maintaining confinement of the optical mode within the MQW region.

The upper and lower central cladding layers may be positioned above the upper near-core cladding layer and below the lower near-core cladding layer, respectively. The central cladding layers provide additional optical confinement to the MQW core layer and maintain the structural stability of the waveguide. The positioning of these layers allows for the optical mode to remain confined within the near-core and MQW regions, optimizing the modulation efficiency of the EAM device. The upper and lower central cladding layers may be composed of materials such as indium phosphide (InP) or related compounds, selected for their refractive index properties that complement the near-core cladding layers and the MQW core. The refractive index of the upper and lower central cladding layers is configured to be compatible with the waveguide design, helping to confine the optical mode and reduce optical losses. The upper and lower central cladding layers may also be doped to adjust their electrical and optical characteristics to support the modulation process.

In one embodiment, the upper grading layer may be disposed between the MQW layer and the upper near-core cladding layer, while the lower grading layer may be disposed between the MQW layer and the lower near-core cladding layer. In this configuration, the grading layers may provide a gradual compositional and refractive index transition directly adjacent to the MQW core, facilitating a smooth integration between the active modulation region and the surrounding near-core cladding layers. The placement of the grading layers in this embodiment is particularly effective in reducing the formation of potential barriers that could impede the movement of electrons and holes between the MQW layer and the cladding regions. Additionally, the continuous compositional grading minimizes the impact of band discontinuities, ensuring that the optical mode remains well-confined within the MQW layer for efficient modulation.

In another embodiment, the upper grading layer may be disposed between the upper near-core cladding layer and the upper central cladding layer, while the lower grading layer may be disposed between the lower near-core cladding layer and the lower central cladding layer. Such a configuration may place the grading layers at the interface between the near-core cladding and central cladding regions, providing a gradual transition that increases optical confinement and maintains waveguide integrity. By positioning the grading layers between the near-core and central cladding layers, this embodiment focuses on maintaining the continuity of the waveguide structure beyond the MQW region, for smooth transitions in optical and material properties throughout the entire device.

FIG. 1D illustrates an example cross-section view of an electro-absorption modulator (EAM) device 140 having a layered structure including a plurality of grading layers, in accordance with one or more embodiments of the present disclosure. As shown in FIG. 1C, the EAM device 140 may include a semiconductor substrate 105, a waveguide mesa 142 formed on the substrate 105, and an electrode structure (not shown) configured to apply an electric field across the waveguide mesa 142. The waveguide mesa 142 may include a buffer layer 130, grading layers 135, 165, 161, 163, 165, a lower peripheral layer 162, a continuous multi-quantum well (MQW) layer 160, an upper peripheral layer 164, a near-core cladding layer 170, a central cladding layer 172, and a distal cladding layer 174. In an example embodiment, these layers may be etched to define the waveguide mesa 142. As shown in FIG. 1D, the height 182 of the waveguide mesa 142 is oriented substantially perpendicular to the interfaces of the various layers within the semiconductor waveguide mesa 142, allowing for the vertical stacking of the layers.

The semiconductor substrate 105 serves as the base upon which the various layers of the waveguide mesa 142 are formed. The buffer layer 130, positioned directly on the substrate 105, may provide lattice matching between the substrate and the subsequent layers to reduce crystal defects. In various embodiments, the buffer layer 130 may also facilitate stress relief and increase the structural stability of the waveguide mesa during epitaxial growth processes.

Above the buffer layer 130, a plurality of grading layers 135 may be included to provide a continuous compositional gradient between the buffer layer 130 and the lower peripheral layer 162. The lower peripheral layer 162 is formed on these grading layers and serves as part of the optical confinement structure for the waveguide. The grading layers 135 optimize the transition between the buffer layer and the lower peripheral layer by adjusting material composition and lattice constants gradually, thereby minimizing the likelihood of defects.

The continuous MQW layer 160 is disposed above the lower peripheral layer 162. This MQW layer 160 functions as the core of the waveguide mesa 142 and is configured to propagate an optical signal through the EAM device 140. Positioned between the lower and upper peripheral layers (162 and 164), the MQW layer 160 serves as the active region where the modulation of the optical signal occurs in response to an electric field applied via the electrode structure. The MQW layer 160 comprises alternating thin semiconductor layers with different bandgaps, enabling electro-absorption modulation.

Grading layers 161 are positioned between the lower peripheral layer 162 and the MQW layer 160. These grading layers 161 provide a gradual transition that facilitates efficient electron and hole movement into the MQW layer 160, minimizing carrier scattering and enhancing modulation efficiency. Similarly, grading layers 163 are provided between the MQW layer 160 and the upper peripheral layer 164. These grading layers 163 establish a smooth compositional gradient, allowing charge carriers to transition effectively between the MQW and the upper peripheral layer, thereby optimizing the device's response time.

The upper peripheral layer 164 is formed above the MQW layer 160 and serves as the counterpart to the lower peripheral layer 162. Together, these layers confine the optical signal within the MQW core 160, preventing leakage and ensuring effective light propagation through the waveguide mesa 142.

Above the upper peripheral layer 164, grading layers 165 may be present to provide a gradual compositional transition to the near-core cladding layer 170. This near-core cladding layer 170 is formed to maintain the confinement of the optical signal within the waveguide structure. The central cladding layer 172 is deposited above the near-core cladding layer 170, and finally, the distal cladding layer 174 is formed as the outermost layer. These cladding layers 170, 172, 174 collectively enhance optical confinement, structural stability, and isolation from external environments.

In some embodiments, the layers of the waveguide mesa 142, including the MQW layer 160, peripheral layers 164, 162, grading layers 135, 165, 161, 163, 165, and cladding layers 170, 172, 174, may be formed, deposited, or epitaxially grown through a single epitaxial growth process, such as Metal-Organic Chemical Vapor Deposition (MOCVD) or Molecular Beam Epitaxy (MBE).

In various embodiments, the continuous MQW layer 160, as well as the upper and lower peripheral layers 164 and 162, may be formed from one or more semiconductor materials. In one embodiment, the upper and lower peripheral layers 164 and 162 may be substantially similar in composition, differing primarily in their placement relative to the continuous MQW layer 160 and the substrate 105. Alternatively, in some embodiments, the upper and lower peripheral layers 164 and 162 may comprise different semiconductor materials, have distinct doping profiles, and/or vary in thickness along the mesa height direction 182. The continuous MQW layer 160, in various embodiments, is configured to propagate light or an optical signal in the propagation direction 188.

By way of a non-limiting example, FIG. 2 illustrates a band diagram 200 for the layered structure of FIG. 1A. The band diagram 200 illustrates the conductor band energy E_{C}, valence band energy E_{V}, Fermi energy E_{F} across the layered structure of FIG. 1A. In some embodiments, and as light enters the layered structure (such as an optical beam, optical signal, and/or the like characterized by a particular wavelength range and/or one or more wavelengths within the particular wavelength range) the light may be transferred through the layered structure until it reaches the absorption region which may use the light to generate a plurality of electrons and holes. For instance, the light 101 may enter through the top peripheral region 120 and/or the light 111 may enter through the bottom peripheral region 110. In both embodiments, the light (e.g., 101 and 111) may flow to the absorption region 114 without being captured either by the peripheral regions (120 and 110) or the collector region 111 (which may include drift layer 112 and collection layer 113) if contacted through the bottom peripheral region 110. As light enters the absorption region 114, free electrons (e.g., shown as electron 102) and free holes (e.g., shown as hole 104) are generated. The free electrons may then be accelerated from the absorption region 114 to the collector region 111 toward the bottom peripheral layer 110 by the electric fields within the absorption region 114 and the collector region 111 which is controlled by the drift layer 113. The free holes, in contrast, are accelerated toward the top peripheral layer 120 by the electric field within the absorption region 114 which is controlled by the drift layer 113. However, this process of accelerating the free electrons 102 and free holes 104 is mitigated, stalled, and/or halted, by the bandgap differentials between the absorption region and the collector region 111 or the top peripheral region 120, respectively.

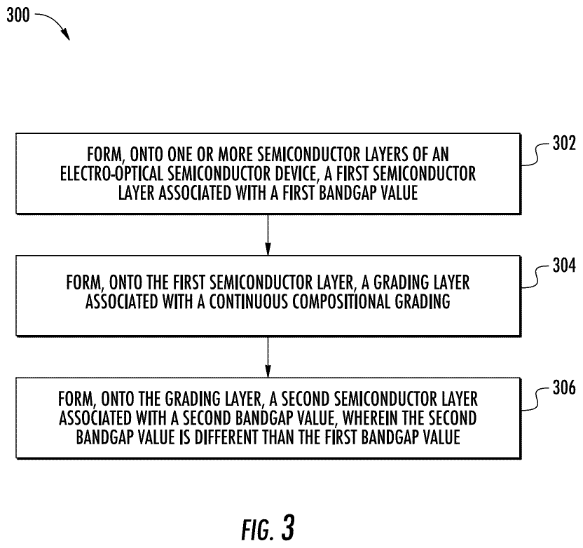

In some embodiments, a grading layer 124 may be formed onto at least the top peripheral layer 120 abutting the absorption region and/or the collection region 111, wherein the grading layer is generated by a continuous compositional grading between the materials of at least the top peripheral layer 120 and/or collection region 111, and the absorption region 114. Such a grading layer may include a plurality of grading layers within the layered structure such as grading layer 122 and grading layer 124. Alternatively, in some embodiments, only one grading layer may be used in the layered structure. The grading layer 124 may be formed by the top peripheral layer 120, and the absorption layer 114 may be grown on the grading layer 124. In some embodiments, only the grading layer 122 may be grown within the layered structure, such that the grading layer 122 is formed on the collection region 111, and the absorption layer 114 is likewise grown on the grading layer 122. In any event, the layered structure 100′ as illustrated in FIG. 1B, may be grown in an ascending direction (e.g., from layer 110 to layer 120). Such disclosure of methods to grow the grading layer(s) 122 and 124 are described in further detail below with respect to FIG. 3.

FIG. 3 illustrates an example flowchart of the process to generate the layered structure comprising at least one grading layer which is used to generate a semiconductor device, such as a photodetector or an EAM device. As shown in block 302, the method 300 may include forming, onto one or more semiconductor layers of an electro-optical semiconductor device, a first semiconductor layer associated with a first bandgap value. For example, in the context of a photodetector, the first semiconductor layer may serve as the collector region, which is typically transparent to the operational wavelength range to allow light to pass through efficiently. In the case of an EAM device, the first semiconductor layer could correspond to part of the waveguide mesa, such as a near-core cladding layer or central cladding layer, depending on the specific structure and configuration. By way of non-limiting example, the first semiconductor layer may be formed onto one or more other semiconductor layers, such as a substrate layer and/or a peripheral layer (e.g., peripheral layer 110) such that the first semiconductor layer is the collection region 112 and 113 and/or a layer between the peripheral layer 120. In some embodiments, such a substrate layer and/or peripheral layer (e.g., peripheral layer 110) may include InP, silicon (Si), and/or the like. In some embodiments, the InP may be p-doped or n-doped depending on the purpose for which the substrate is used for (e.g., the peripheral layer may have a different doping than the collection region).

In some embodiments, the absorber region 114 includes at least one of InGaAs, InGaAsP, InGaAlAs, AlGaAs, AlGaAsP, SiGe, AlGaN, and/or InGaN. In some embodiments, such a listing of materials for the absorber region includes materials of a lower bandgap than the surrounding peripheral region (e.g., the top peripheral region 120), the collector region (e.g., drift layer 113 and collection layer 112), and/or the peripheral region located remote from the absorption region (e.g., peripheral region 110). In some embodiments, the absorption region 114 includes intrinsic (and/or un-doped) InGaAs, InGaAsP, InGaAlAs, AlGaAs, AlGaAsP, SiGe, AlGaN, and/or InGaN; and/or doped InGaAs, InGaAsP, InGaAlAs, AlGaAs, AlGaAsP, SiGe, AlGaN, and/or InGaN. In some embodiments, and as described more fully below with respect to FIG. 3, the layered structure 100, 100′ is formed on an InP substrate, such as the at least one of the peripheral regions (e.g., 120 or 110) comprising InP or the collection region (e.g., 112 and 113) comprising InP, such that each layer of the layered structure 100, 100′ (e.g., the absorption region 114) are lattice-matched to InP. In some embodiments, such a layer comprising InP (e.g., peripheral region 120 and/or 110 and/or collection region 112 and 113) may be doped to introduce impurities to the materials, wherein the doping may include a p-doping or an n-doping.

In some embodiments, the first semiconductor layer may include materials such as InP, indium gallium arsenide phosphide (InGaAsP), gallium arsenide (GaAs), silicon (Si), gallium nitride (GaN), and/or the like. Such materials used to form the first semiconductor layer may include a first bandgap, such as a larger bandgap as compared to a bandgap of an absorption region 114.

In some embodiments, the disclosure provided herein may include an electro-optical semiconductor device that provides that the first semiconductor layer's bandgap and the second semiconductor's bandgap is greater than or equal to 0.1 eV. Thus, in some embodiments, the difference may include 0.1 eV, 0.11 eV, 0.12 eV, 0.13 eV, 0.14 eV, 0.15 eV, 0.16 eV, 0.17 eV, 0.18 eV, 0.19 eV, 0.2 eV, and/or the like. In some embodiments, the differential between the first semiconductor layer and the second semiconductor layer may include steps of 0.01 eV, 0.001 eV, 0.0001 eV, 0.00001 eV, 0.000001 eV, and/or the like. The first semiconductor layer may, in some embodiments, be deposited onto a substrate via chemical vapor deposition (CVD).

As shown in block 304, method 300 may include forming, onto the first semiconductor layer, a grading layer associated with a continuous compositional grading. As described herein, in the context of a photodetector, the grading layer may be formed between the absorber region and the collector region or formed between the absorber region and the peripheral layer. In the EAM device, the grading layer may be formed between key layers within the waveguide mesa, such as formed between the MQW core layer and the near-core cladding layers or formed between the near-core cladding layers and the central cladding layers. In some embodiments, the grading layer may be formed onto the first semiconductor layer by gradually applying the material of the second semiconductor layer missing from the first semiconductor layer to the first semiconductor layer. In some embodiments, this continuous grading to generate the grading layer is done by an epitaxy process such as a metal organic chemical vapor deposition (e.g., MOCVD) process, a molecular beam epitaxy (MBE) process, and/or other epitaxy process known in the art.

For instance, a MOCVD process may include the deposition of thin layers of atoms onto the first semiconductor layer. By way of non-limiting example, the grading layer may include a total thickness of between and including approximately 50-500 nm.

By way of non-limiting example, if the first semiconductor layer is InP and the intended second semiconductor layer is InGaAs, then the grading layer material within the epitaxy process may include only InP molecules as an initial grading layer material. For instance, the epitaxy process may be controlled by a chemical equation directed to the second semiconductor layer such as In₁₋ₓGaₓAs_{y}P_{1-y} wherein the initial values of x and y are zero (e.g., x=0 and y=0) such that only InP is formed into the epitaxy process, and as the epitaxy process continues, the x value and the y value are gradually increased.

In embodiments in which the first semiconductor layer is InP and the second semiconductor layer is InGaAsP, the grading layer material within the epitaxy process may include only InP molecules as an initial grading layer material. For instance, the epitaxy process may be controlled by a chemistry equation directed to the second semiconductor layer such as In₁₋ₓGaₓAs_{y}P_{1-y} wherein the initial values of x and y are zero (e.g., x=0 and y=0) such that only InP is formed into the epitaxy process, and as the epitaxy process continues, the x value, the y value, and the z value are gradually increased.

In embodiments in which the first semiconductor layer is InP and the second semiconductor layer is InGaAlAs, the grading layer material within the epitaxy process may include only InP molecules as an initial grading layer material. For instance, the epitaxy process may be controlled by a chemistry equation directed to the second semiconductor layer such as In_{1-x-y}GaₓAl_{y}As_{z}P_{1-z} wherein the initial values of x, y, and z are zero (e.g., x=0, y=0, and z=0) such that only InP is formed into the epitaxy process, and as the epitaxy process continues, the s, x, y, and z values are gradually increased.

In those embodiments where the first semiconductor layer is InGaAsP and the second semiconductor layer is InGaAs, then the grading layer material within the epitaxy process may include only InGaAsP molecules as an initial grading layer material. For instance, the epitaxy process may be controlled by a chemical equation directed to the second semiconductor layer such as In₁₋ₓGaₓAs_{y}P_{1-y} y wherein the initial value of x and y are zero (e.g., x=0 and y=0) such that only InGaAs is formed into the epitaxy process, and as the epitaxy process continues, the x value is gradually increased.

In those embodiments where the first semiconductor layer is InGaAsP and the second semiconductor layer is InGaAlAs, then the grading layer material within the epitaxy process may include only InGaAsP molecules as an initial grading layer material. For instance, the epitaxy process may be controlled by a chemistry equation directed to the second semiconductor layer such as In_{1-x-y}GaₓAl_{y}As_{z}P_{1-z} wherein the initial values of x, y, and z are zero (e.g., x=0, y=0, and z=0) such that only InGaAsP is formed into the epitaxy process, and as the epitaxy process continues, the x value and the y value are gradually increased.

In those embodiments where the first semiconductor layer is GaAs and the second semiconductor layer is AlGaAsP, then the grading layer material within the epitaxy process may include only GaAs molecules as an initial grading layer material. For instance, the epitaxy process may be controlled by a chemistry equation directed to the second semiconductor layer such as Ga₁₋ₓAlₓAs_{y}P_{y} wherein the initial values of x and y (e.g., x=0 and y=0) such that only InGaAsP is formed into the epitaxy process, and as the epitaxy process continues, the x value and the y value are gradually increased.

In those embodiments where the first semiconductor layer is Si and the second semiconductor layer is SiGe, then the grading layer material within the epitaxy process may include only Si molecules as an initial grading layer material. For instance, the epitaxy process may be controlled by a chemistry equation directed to the second semiconductor layer such as Si_{1—x}Geₓ wherein the initial value of x is zero (e.g., x=0) such that only Si is formed into the epitaxy process, and as the epitaxy process continues, the x value is gradually increased.

In those embodiments where the first semiconductor layer is GaN and the second semiconductor layer is AlGaN, then the grading layer material within the epitaxy process may include only GaN molecules as an initial grading layer material. For instance, the epitaxy process may be controlled by a chemistry equation directed to the second semiconductor layer such as AlₓGa₁₋ₓN wherein the initial value of x is zero (e.g., x=0) such that only GaN is formed into the epitaxy process, and as the epitaxy process continues, the x value is gradually increased.

In those embodiments where the first semiconductor layer is GaN and the second semiconductor layer is InGaN, then the grading layer material within the epitaxy process may include only GaN molecules as an initial grading layer material. For instance, the epitaxy process may be controlled by a chemistry equation directed to the second semiconductor layer such as AlₓGa₁₋ₓN wherein the initial value of x is zero (e.g., x=0) such that only GaN is formed into the epitaxy process, and as the epitaxy process continues, the x value is gradually increased.

As shown in block 306, method 300 may include forming, onto the grading layer, a second semiconductor layer associated with a second bandgap value, wherein the second bandgap value is different than the first bandgap value. In the context of a photodetector, the second semiconductor layer may be the absorber region if the grading layer is formed on the collector region, or the peripheral layer if the grading layer is formed on the absorber region. In the EAM device, the second semiconductor layer may be adjacent cladding layers within the waveguide mesa, depending on the specific configuration. By way of non-limiting example, the second semiconductor layer may be generated by slowly introducing the materials of the second semiconductor layer within the epitaxy process. For instance, and as discussed above, if the first semiconductor layer is InP and the second semiconductor layer is InGaAs, then the materials of the first semiconductor layer that differ from the second semiconductor layer (e.g., phosphide, P) may be gradually removed from within the epitaxy process such that the grading layer by the end of the grading layer formation only includes the second semiconductor layer materials. By way of completion of disclosure, such process of the formation of the second semiconductor layer may be used for at least each of the first semiconductor layer materials, grading layer materials, and second semiconductor layers as described above (e.g., InP, InGaAs, InGaAsP, InGaAlAs, GaAs, AlGaAs, AlGaAsP, Si, SiGe, GaN, AlGaN, InGaN, and/or the like).

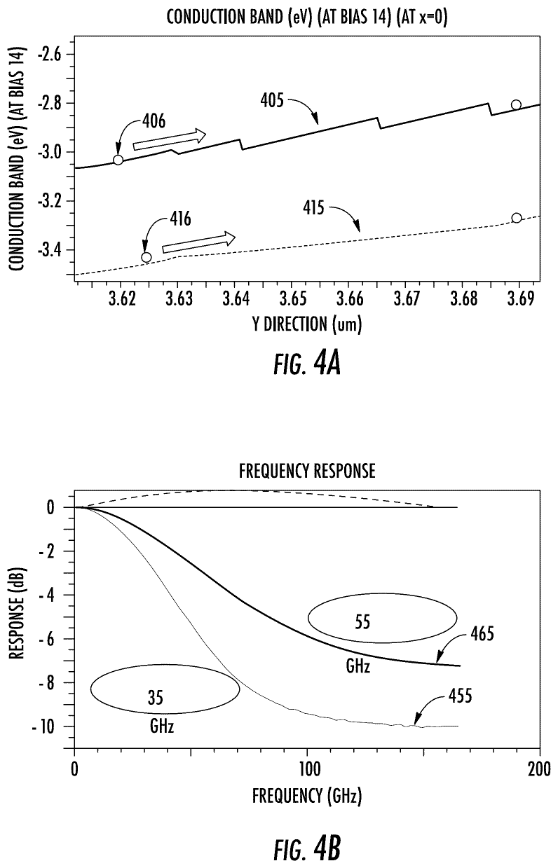

FIG. 4A illustrates a conduction band diagram of the layered structure's performance of the conduction band with respect to an electron's movement in a layered structure comprising a plurality of grading layers as compared to the electron's movement in the layered structures that do not include a plurality of grading layers. By way of non-limiting example, the present disclosure provides an improvement over the prior art by providing a continuous grading between semiconductor layers comprising different bandgaps (e.g., a first semiconductor layer and the second semiconductor layer). For instance, FIG. 4A provides a graph-line 415 to show an electron's 416 movement within a layered structure used to generate a semiconductor, wherein the layered structure includes a grading layer. For instance, line 415 shows that the electron 416 may move in an unimpeded manner across a y-direction (e.g., between semiconductor layers such as absorption region 114 and the collection region 113 and 112 toward the peripheral region 110 and/or the free holes toward the peripheral region 120). For instance, line 405 indicating a step structure between the semiconductor layers (e.g., a first semiconductor layer and a second semiconductor layer) shows a potential trapping (e.g., by bumps and/or differences in bandgap height) of the electrons (406) as they move along the x-axis.

FIG. 4B illustrates the frequency response comparison of the layered structure's performance in frequency response, wherein the layered structure includes a plurality of grading layers as compared to the frequency response in the layered structures that do not include a plurality of grading layers. By way of non-limiting example, FIG. 4B depicts the frequency response of the layered structure where grading layers have been formed to help electrons and holes move through the layered structure at better frequency responses, as shown as line 465 indicating higher response over different frequencies. In comparison, layered structures not comprising any grading layers has a lower frequency response (e.g., line 435 indicating lower response values—decibels—over different frequencies). By way of non-limiting example, such a continuous compositional grading (e.g., like that shown as FIGS. 1A and 1B]) results in an improved frequency response relative to non-continuous compositional grading (e.g., such as the frequency response shown as line 435 of FIG. 4).

Further, and as described above with respect to FIG. 3, a MOCVD system may act to control the introduction of certain materials from the source materials to form the first semiconductor layer, the grading layer, and/or the second semiconductor layer (e.g., controlling the insertion of InP materials for the first semiconductor layer, the insertion of the InGaAsP materials to form the grading layer, and/or the insertion of the InGaAs materials to form the second semiconductor layer) by controlling the insertion of the materials based on the chemical equations discussed above. By way of a non-limiting example, the continuous grading layer(s) may be generated by a continuous composition grading process having a change rate of approximately 0 eV to 0.2 eV between grading layers.

Based on the continuous compositional grading process and the epitaxy processes described herein to form the grading layer(s), a step size between the layers of the continuous grading layer is approximately equal to zero (i.e., the grading layer is continuous and does not include any steps that could mitigate electron or hole movement). For instance, and as discussed herein with respect to the layered structure described in FIGS. 1A and 1B, the example bandgap diagram described in FIG. 2, and the method described in FIG. 3, the continuous compositional grading process may be designed to generate a continuous grading layer(s) between a first semiconductor layer and a second semiconductor layer such that the difference between each layer within the continuous grading layer is approximately equal to 0 eV (e.g., such as in steps of 0.00001 eV, 0.0001 eV, 0.001 eV, 0.01 eV, and/or the like). In contrast, a non-continuous compositional grading may include grading layers of at least 0.02 eV).

In some embodiments, each layer of the continuous grading layer may comprise a difference between surrounding layers of the continuous grading layers so miniscule such that the continuous grading layer is functionally continuous and allows the electrons and/or holes to move along an un-impeded path. In this manner, the grading layer(s) of the continuous grading layer should include a depth as close to the depth of the layers directly adjacent to the grading layer in each instance (e.g., a bandgap step in the range between approximately 0 eV and 0.02 eV). For instance, each grading layer may comprise a depth similar to or the same as the grading layer(s) surrounding each grading layer (i.e., each grading layer comprises a similar depth to the grading layer(s) directly adjacent to each grading layer.

Many modifications and other embodiments of the disclosure set forth herein will come to mind to one skilled in the art to which these disclosures pertain having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purpose of limitation.

1. A photodetector, comprising:
a collector region disposed on one or more semiconductor layers, wherein the collector region comprises collector material that is substantially transparent to an operational wavelength range of the photodetector;
an absorber region disposed above the collector region along a detection axis of the photodetector;
a grading layer disposed adjacent the absorber region along the detection axis, wherein the grading layer comprises a plurality of layers defining a continuous compositional grading; and
a peripheral layer disposed above the grading layer along the detection axis,
wherein the operational wavelength range is approximately 940 nm to 1700 nm.

2. The photodetector of claim 1, wherein the collector region has a first thickness in a direction that is substantially parallel to the detection axis, and wherein the absorber region has a second thickness in the direction that is substantially parallel to the detection axis.

3. The photodetector of claim 1, further comprising:
an optical window disposed above the absorber region such that light passes through the optical window before reaching the absorber region, wherein the optical window is configured for use with a multi-mode optical fiber.

4. The photodetector of claim 1, wherein the absorber region comprises absorber material, wherein the absorber material comprises at least one of indium gallium arsenide (InGaAs), indium gallium arsenide phosphide (InGaAsP), or indium gallium aluminum arsenide (InGaAlAs).

5. The photodetector of claim 4, wherein the absorber material is lattice-matched to indium phosphide (InP).

6. The photodetector of claim 1, wherein the collector region comprises collector material, wherein the collector material comprises at least one of indium phosphide (InP), indium gallium arsenide phosphide (InGaAsP), or indium gallium aluminum arsenide (InGaAlAs).

7. The photodetector of claim 6, wherein the collector material is lattice-matched to indium phosphide (InP).

8. The photodetector of claim 7, wherein the peripheral layer is lattice-matched to the collector material.

9. The photodetector of claim 1, wherein the peripheral layer comprises p-type doped material, wherein the p-type doped material comprises at least one of indium phosphide (InP), indium aluminum arsenide (InAlAs), indium gallium arsenide phosphide (InGaAsP), or indium gallium aluminum arsenide (InGaAlAs).

10. The photodetector of claim 1, wherein the grading layer is disposed between the absorber region and the peripheral layer.

11. The photodetector of claim 1, wherein the grading layer is disposed between the absorber region and the collector region.

12. An electro-absorption modulator (EAM) device, comprising:
a semiconductor substrate; and
a waveguide mesa formed on the semiconductor substrate, wherein the waveguide mesa further comprises:
a multi-quantum well (MQW) core layer;
an upper near-core cladding layer disposed above the MQW layer;
an upper grading layer disposed adjacent the upper near-core cladding layer, wherein the upper grading layer comprises a plurality of layers defining a continuous compositional grading; and
an upper central cladding layer disposed above the upper grading layer; and

[symbol]

13. The EAM device of claim 12, wherein the MQW layer comprises gallium arsenide (GaAs), indium phosphide (InP) based semiconductor materials, or silicon-based semiconductor.

14. The EAM device of claim 12, wherein the MQW layer comprises III-V semiconductor materials, wherein the III-V semiconductor materials comprises at least one of indium aluminum gallium arsenide (InAlGaAs), indium gallium arsenide phosphide (InGaAsP), silicon germanium (SiGe), or Si—SiGe composition.

15. The EAM device of claim 12, wherein MQW is formed using a single epitaxial growth process.

16. The EAM device of claim 12, wherein the waveguide mesa further comprises:
a lower near-core cladding layer disposed below the MQW layer;
a lower grading layer disposed adjacent the lower near-core cladding layer, wherein the lower grading layer comprises a plurality of layers defining a continuous compositional grading; and
a lower central cladding layer disposed below the lower grading layer.

17. The EAM device of claim 16, wherein the upper near-core cladding layer and the lower near-core cladding layer comprise at least one of n-type doped aluminum gallium arsenide (AlGaAs) or indium gallium arsenide phosphide (InGaAsP) semiconductor material or p-type doped aluminum AlGaAs or InGaAsP semiconductor material.

18. The EAM device of claim 16, wherein the upper central cladding layer and the lower central cladding layer comprise at least one of n-type doped indium phosphide (InP) semiconductor material or p-type doped InP semiconductor material.

19. The EAM device of claim 16, wherein the upper grading layer is disposed between the MQW layer and the upper near-core cladding layer, and the lower grading layer is disposed between the MQW layer and the lower near-core cladding layer.
